(19) United States
(12) Patent Application Publication
(10) Pub. No.: US 2010/0032801 A1
(43) Pub. Date: Feb. 11, 2010

(54) CAPACITOR FORMED IN INTERLEVEL DIELECTRIC LAYER

(75) Inventors: Jarvis Benjamin Jacobs, Murphy, TX (US); Max Walthour Lippitt, Rockwall, TX (US); Scott Kelly Montgomery, Rowlett, TX (US); Robert William Murto, McKinney, TX (US); Byron Lovell Williams, Plano, TX (US); Duofeng Yue, Plano, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/538,735

(22) Filed: Aug. 10, 2009

Related U.S. Application Data
(60) Provisional application No. 61/087,238, filed on Aug. 8, 2008.

(51) Int. Cl. H01L 29/92; H01L 21/02

(52) U.S. Cl. 257/532; 438/386; 257/E21.008; 257/E29.343

(57) ABSTRACT

An capacitor is formed in an interlevel dielectric (ILD) layer of the integrated circuit (IC) by etching vertical trenches through the ILD and depositing conformal layers of a bottom electrode metal, a capacitor dielectric and a top electrode metal. The capacitor can attain a capacitance density of 20 nanofarads/mm² in a 1 micron thick ILD, and is suitable for replacing external capacitors in a circuit containing the IC with external circuit elements. The disclosed fabrication methods are compatible with aluminum or copper interconnects.

This is a non-provisional of Application No. 61/087,238 filed Aug. 8, 2009, the entirety of which is incorporated herein by reference.

### BACKGROUND

This invention relates to the field of semiconductor devices; and, more particularly, to the fabrication of integrated circuits including capacitors.

Integrated circuits (ICs) are frequently mounted on circuit boards with external electronic components such as capacitors and resistors which are electrically connected to the ICs. It is desirable to incorporate external components into ICs to reduce the physical sizes of the circuit boards, improve performance of the ICs, and reduce overall costs of electronic products. Capacitors fabricated in interconnect structures of ICs (such as have capacitance densities below 5 nanofarads/mm²) use processes which do not require added photolithographic operations which prohibits incorporation of many external capacitors. Capacitors fabricated using gate dielectric layers of MOS transistors frequently cannot tolerate voltage levels used in external capacitors, such as above 3 volts, which also prohibits incorporation of many external capacitors. Capacitors fabricated in ICs with capacitance densities above 10 nanofarads/mm² and capable of 3 to 5 volt operation, e.g., add significant fabrication cost and complexity to the ICs, which defeat the goal of reducing overall costs of the associated electronic products.

There is a need to be able incorporate external capacitors into ICs to be able to attain capacitance densities above 20 nanofarads/mm² and operation voltages above 3 to 5 volts without significantly adding photolithographic or other steps to the IC fabrication process sequence.

### SUMMARY

The invention enables capacitors to be provided on integrated circuits (ICs) to meet the above need.

In a described embodiment, a three-dimensional capacitor is embedded within an interlevel dielectric (ILD) layer of an IC to provide a capacitance density of 20 nanofarads/mm² or more with an ILD layer of 1 micron thickness or more, and a capacitance of 40 nanofarads/mm² or more with an ILD layer of 2 microns thickness or more. In one example method of fabrication, the embedded capacitor is formed by etching to provide vertical trenches to a lower interconnect element in an ILD layer, depositing a conformal metal bottom electrode, depositing a conformal dielectric layer over the bottom electrode, and depositing a conformal metal top electrode over the dielectric layer. The described capacitor may be integrated into ICs with copper or aluminum interconnects.

### BRIEF DESCRIPTION OF THE DRAWINGS

FIG. 1 is a perspective illustration of the process of incorporating an external capacitor into an IC.

FIGS. 2A-2G are cross-sectional views of an IC embodying a capacitor and formed according to a first example embodiment of principles of the invention.

FIGS. 3A-3C are cross-sectional views of an IC embodying a capacitor and formed according to a second example embodiment of principles of the invention.

FIGS. 4A-4C are cross-sectional views of an IC embodying a capacitor and formed according to a third example embodiment of principles of the invention.

FIGS. 5A-5B are cross-sectional views of an IC embodying a capacitor and formed according to a fourth example embodiment of principles of the invention.

FIGS. 6A-6E are top views of example capacitor trench patterns usable with various embodiments of the invention.

### DETAILED DESCRIPTION OF EXAMPLE EMBODIMENTS

The principles of the invention are described as applied to example implementations for incorporating an external capacitor into an integrated circuit (IC), wherein capacitance densities above 20 nanofarads/mm² and operation above 3 to 5 volts are attainable without adding many photolithographic or other steps to an IC fabrication process. In the example embodiments, an external capacitor is replaced with an on-chip three-dimensional (3-D) capacitor, embedded by etching a set of vertically extending holes in an interlevel dielectric (ILD) layer, forming a first layer of metal within the holes, forming a dielectric layer over the first metal layer, forming a second metal layer over the first metal layer, conducting a masked etch to define capacitor boundaries, and depositing another dielectric layer to seal capacitor edges. For the example embodiments, a capacitance density of 20 nanofarads/mm² or more is attainable in an ILD layer 1 micron thick, and a capacitance density of 40 nanofarads/mm² is attainable in an ILD layer 2 microns thick.

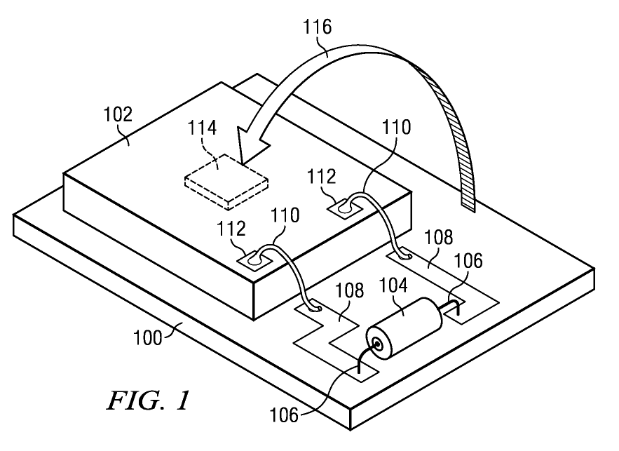

FIG. 1 illustrates incorporating an external capacitor into an IC. A circuit board 100 has mounted on it an IC 102 and an external capacitor 104. The external capacitor 104 is electrically connected to the IC 102 through capacitor leads 106 which are electrically connected to conductive runs 108 on the circuit board 100, which are connected to wire bonds 110 that are connected to bond pads 112 on a top surface of the IC 102. The bond pads 112 are connected to a circuit in the IC 102 by interconnects. The example implementations of the invention enable replacing the external capacitor 104 with an on-chip embedded capacitor 114 as schematically indicated by an arrow 116.

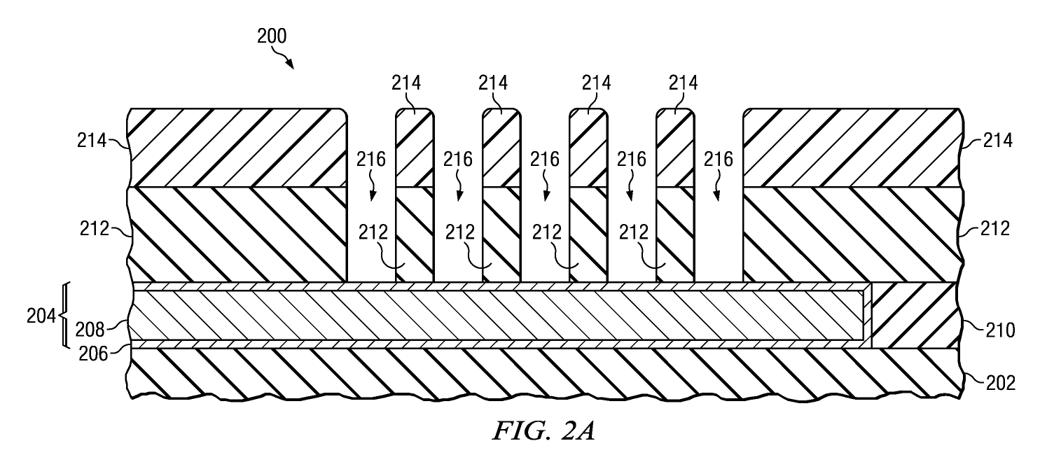

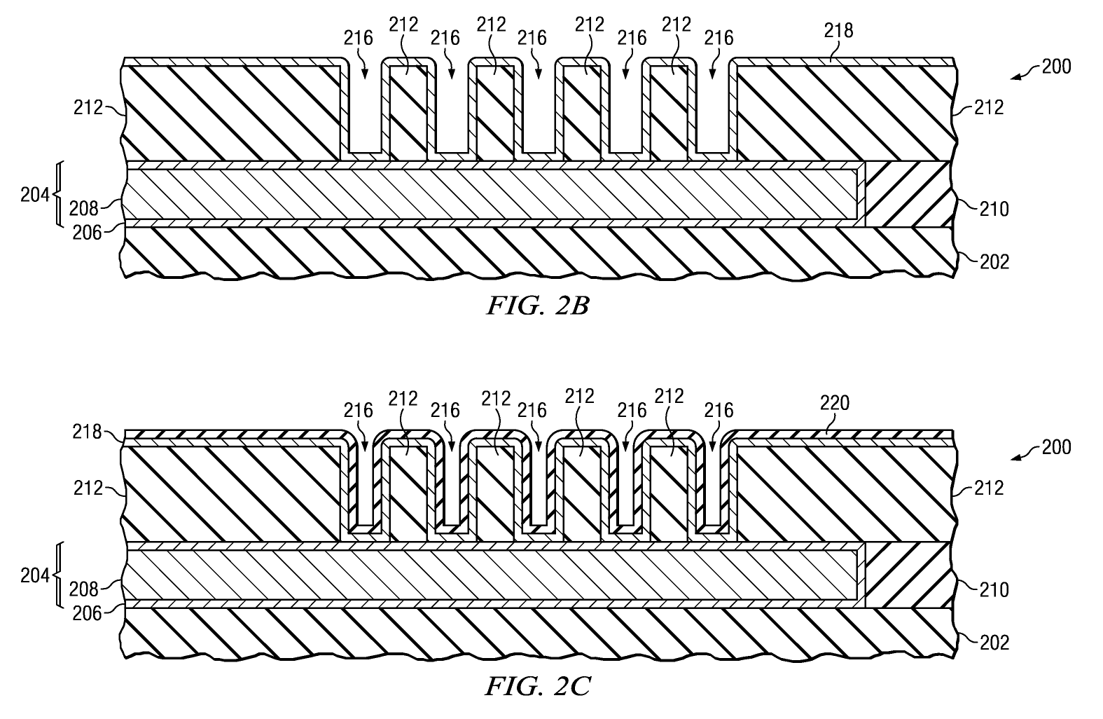

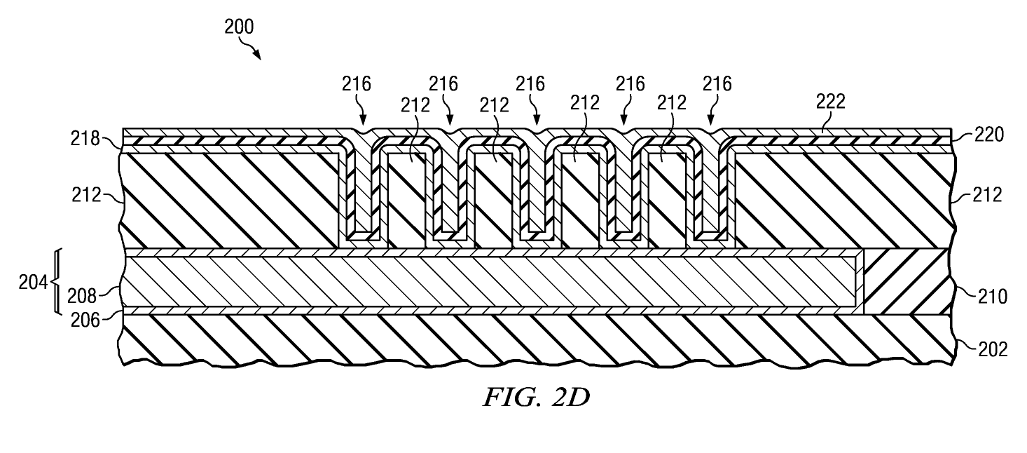

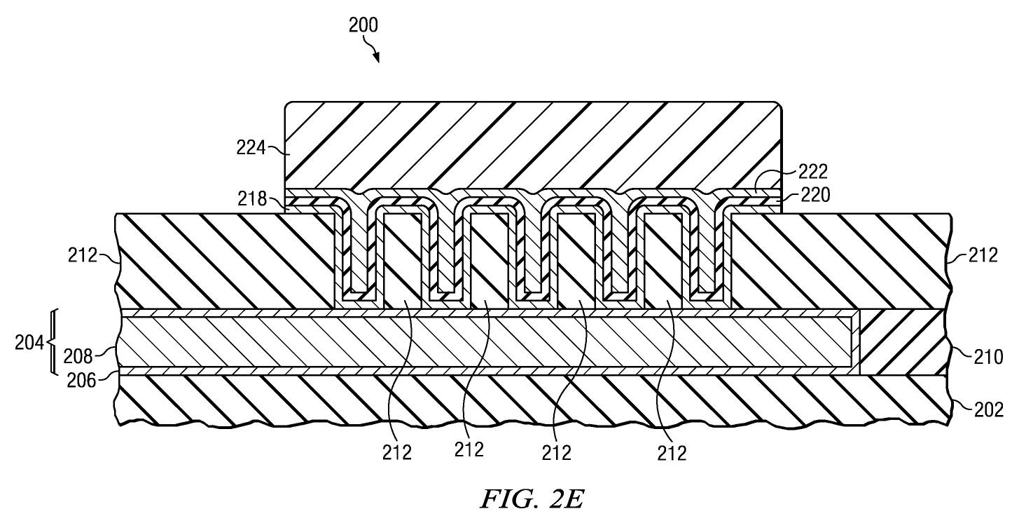

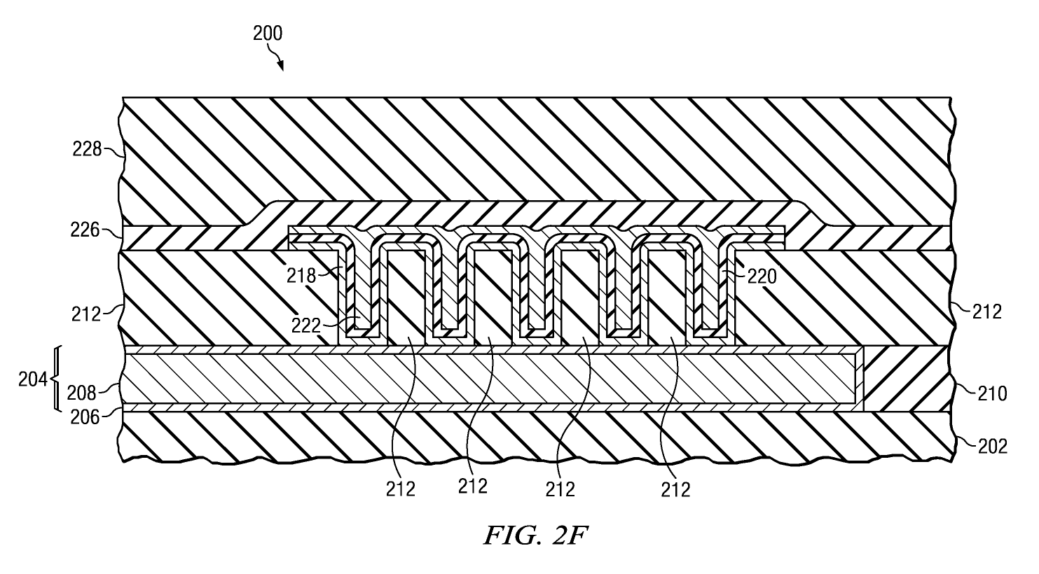

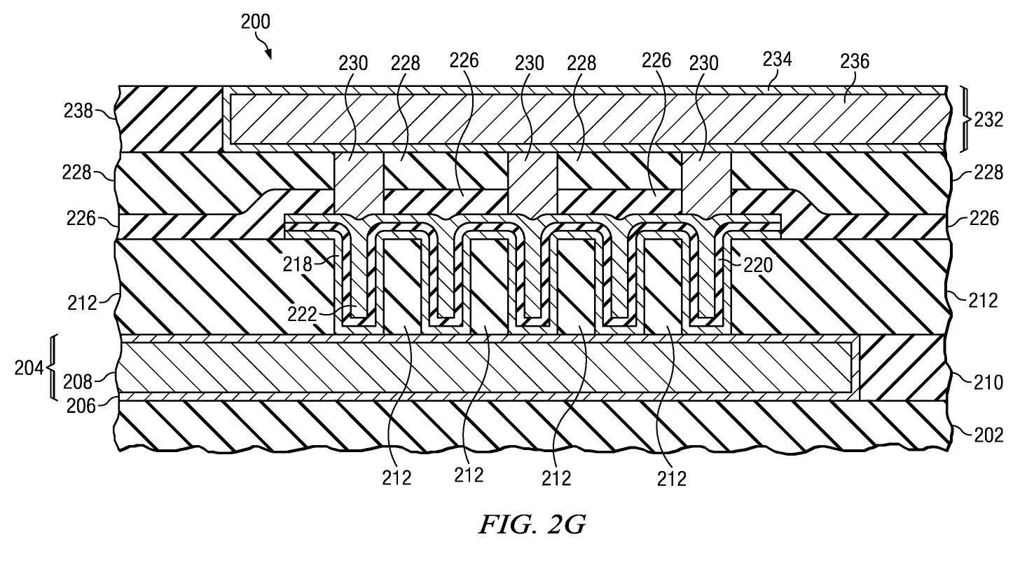

FIGS. 2A-2G are cross-sectional views of an IC with a capacitor formed according to a first embodiment of the invention. The illustrated example includes has aluminum interconnects containing an on-chip three-dimensional (3-D) embedded capacitor.

Referring to FIG. 2A, the IC 200 includes a first ILD layer 202 such as silicon dioxide or a low-k dielectric electrically insulating material (having a dielectric constant lower than that of silicon dioxide, known as a low-k material) such as organosilicate glass (OSG), carbon-doped silicon oxides (SiCO or CDO) or methylsilsesquioxane (MSQ). The first ILD layer 202 may be, e.g., 100 to 2000 nanometers thick, depending on its position in the interconnect structure of the IC 200. A first metal interconnect element 204 including a first liner metal 206 (e.g., titanium nitride (TiN) or tantalum nitride (TaN), or possibly titanium (Ti) or tantalum (Ta), such as 3 to 20 nanometers thick) and a first aluminum element 208 (e.g., 100 to 1000 nanometers thick) is formed on a top surface of the first ILD layer 202, such as by depositing a liner metal and aluminum, defining the first metal interconnect using photolithography, and removing unwanted aluminum and liner metal by etching. The first metal interconnect element 204 may be formed by other processes. A first intra-metal dielectric (IMD) layer 210 is formed on the top surface of the first ILD layer 202 adjacent to the first metal interconnect element 204, such as of silicon dioxide formed by decomposition of tetraethyl orthosilicate (also known as tetraethoxysilane or TEOS), or by deposition of a silicate containing liquid such as spin-on glass. A first portion of a second ILD layer 212 (preferably 1 to 2 microns thick, but possibly 500 nanometers to 5 microns thick, and also, e.g., silicon dioxide or an electrically insulating material with a dielectric constant lower than silicon dioxide, OSG, SiCO or MSQ) is formed on a top surface of the first metal interconnect element 204 and the first IMD layer 210, such as by chemical vapor deposition (CVD) or plasma enhanced CVD (PECVD). A thickness of the first portion of a second ILD layer 212 may be adjusted to obtain a desired capacitance from the on-chip capacitor and to obtain desired performance from the IC.

A capacitor trench photoresist pattern 214 is formed on a top surface of the second ILD layer 212, using photolithography methods such as used to form interconnect via patterns, to define regions for etching capacitor trenches. Capacitor trenches 216 are etched into the second ILD layer 212 to expose the first liner metal 206, using etching methods such as used to form interconnect via holes. The capacitor trenches 216 are preferably a minimum width supported by photolithographic and etching processes available for fabrication of the IC 200 and consistent with subsequent formation of capacitor metal and dielectric layers in the capacitor trenches 216.

FIG. 2B depicts the IC 200 after formation of a capacitor bottom electrode metal layer 218 on the top surface of the second ILD layer 212 and surfaces of the second ILD layer 212 and first interconnect element 204 in the capacitor trenches 216. The layer 218 may, e.g., be preferably 10 to 30 nanometers thick layer of TiN deposited by physical vapor deposition (PVD), an ionized metal plasma (IMP) process, CVD or atomic layer deposition (ALD). It may also, e.g., be TaN deposited by PVD, IMP, CVD or ALD; aluminum deposited by CVD; tungsten (W) deposited by ALD; Ta deposited by deposited by PVD or IMP; Ti deposited by PVD or IMP; or other conducting material preferably having an electrical resistivity below 100 micro-ohm-cm and capable of being deposited in the capacitor trenches 216 to form a continuous layer and exhibit sufficient adhesion to the second ILD layer 212. The bottom electrode layer 218 makes electrical contact to the first liner metal 206.

FIG. 2C depicts the IC 200 after formation of a capacitor dielectric layer 220 which may, e.g., be preferably 5 to 15 nanometers thick, but possibly 3 to 40 nanometers thick, and preferably a high-k dielectric material, such as Al₂O₃, HfO₂, Ta₂O₅, or ZrO₂, or a combination of high-k materials, deposited by ALD or metal organic CVD (MOCVD) processes, or metal deposition followed by oxidation, on a top surface of the bottom electrode layer 218 to form a continuous insulating layer.

FIG. 2D depicts the IC 200 after formation of a capacitor top electrode metal layer 222 on a top surface of the capacitor dielectric layer 220. Layer 222 may, e.g., be preferably 10 to 50 nanometers thick, and preferably TiN deposited by a PVD or an IMP process, but possibly TaN deposited by PVD or IMP; aluminum deposited by CVD; W deposited by ALD; Ta deposited by deposited by PVD or IMP; Ti deposited by PVD or IMP; or other conducting material with an electrical resistivity preferably below 100 micro-ohm-cm and capable of being deposited in the capacitor trenches 216 to form a continuous layer and exhibit sufficient adhesion to the on-chip 3-D embedded capacitor dielectric layer 220. The material used for the top electrode layer 222 need not be the same material or thickness as the material used for the bottom electrode layer 218. A top surface of the top electrode layer 222 is preferably smooth and contains no voids. An optional additional metal layer, such as tungsten or aluminum, may be formed on the top surface of the top electrode layer 222 to improve a surface morphology of the embedded capacitor.

FIG. 2E depicts the IC 200 at a further stage of fabrication. A capacitor plate photoresist pattern 224 is formed on the top surface of the capacitor top electrode metal layer 222 using photolithography to define lateral boundaries of the capacitor. Material in the bottom electrode layer 218, capacitor dielectric layer 220, and top electrode layer 222 outside the lateral boundaries of the capacitor is removed by etching. The etching process is performed in a manner that results in the top electrode layer 222 and bottom electrode layer 218 remaining electrically isolated from each other.

FIG. 2F depicts the IC 200 after formation of an optional conformal dielectric sidewall layer 226 and a second portion of the second ILD layer 228. The conformal dielectric sidewall layer 226 is preferably silicon nitride, but possibly silicon dioxide or layers of silicon dioxide and silicon nitride, between 10 and 100 nanometers thick, and is formed on a top surface and lateral surfaces of the top electrode layer 222, and lateral surfaces of the capacitor dielectric layer 220 and bottom electrode layer 218. Deposition of the conformal dielectric sidewall layer 226 is preferably performed by PECVD, but any method of deposition compatible with fabrication of the IC 200 is may be used. The second portion of the second ILD layer 228 is, e.g., between 15 and 100 nanometers thick, is formed on a top surface of the conformal dielectric sidewall layer 226, and is preferably composed of the same material as, and deposited by the same process as, the first portion of the second ILD layer 212. The combined first and second portions of the second ILD layer 212, 228 are, e.g., as thick as or thicker than the first ILD layer 202.

FIG. 2G depicts the IC 200 after formation of the embedded capacitor and associated electrical connections are completed. Interconnect vias 230 are formed in the second portion of the second ILD layer 228 and conformal dielectric sidewall layer 226 to contact the top electrode layer 222. The interconnect vias 230 may be formed of tungsten, aluminum, or other conducting material, by photolithography, etching, and metal deposition. An optional liner metal may also be formed to inhibit diffusion of the interconnect via metal into the second ILD layer 228.

Still referring to FIG. 2G, a second metal interconnect element 232 is formed on a top surface of the second ILD layer 228 so as to make electrical contact to the interconnect vias 230. The second metal interconnect element 232 is, e.g., formed by a similar set of processes as used to form the first metal interconnect element 204, and includes a second liner metal 234 (e.g., TiN or TaN, or possibly Ti or Ta, such as 1 to 20 nanometers thick) and a second aluminum element 236 (e.g., such as 100 to 1000 nanometers thick). The second metal interconnect element 232 is, e.g., as thick as, or thicker than, the first metal interconnect element 204. A second IMD layer 238 is formed on the top surface of the second ILD layer 228 adjacent to the second metal interconnect element 236, e.g., of the same material and formed by the same process as the first IMD layer 210.

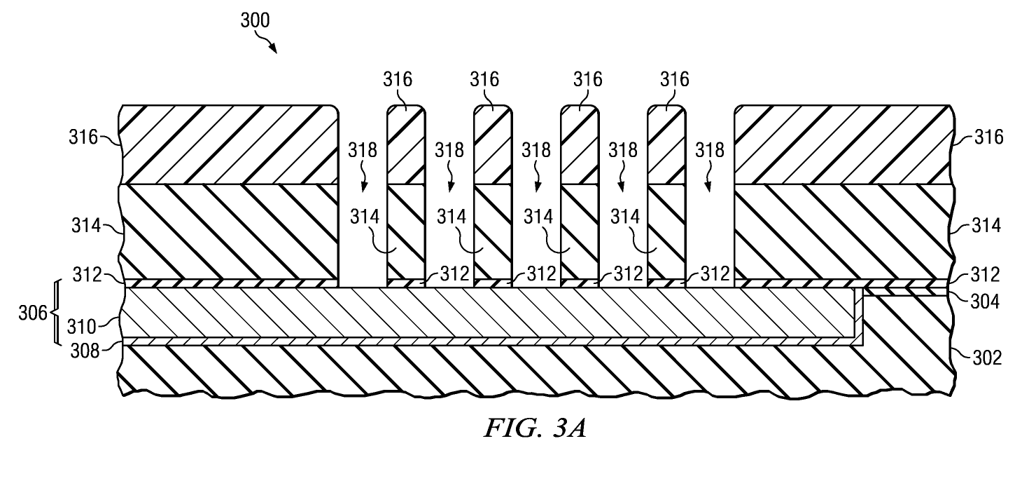

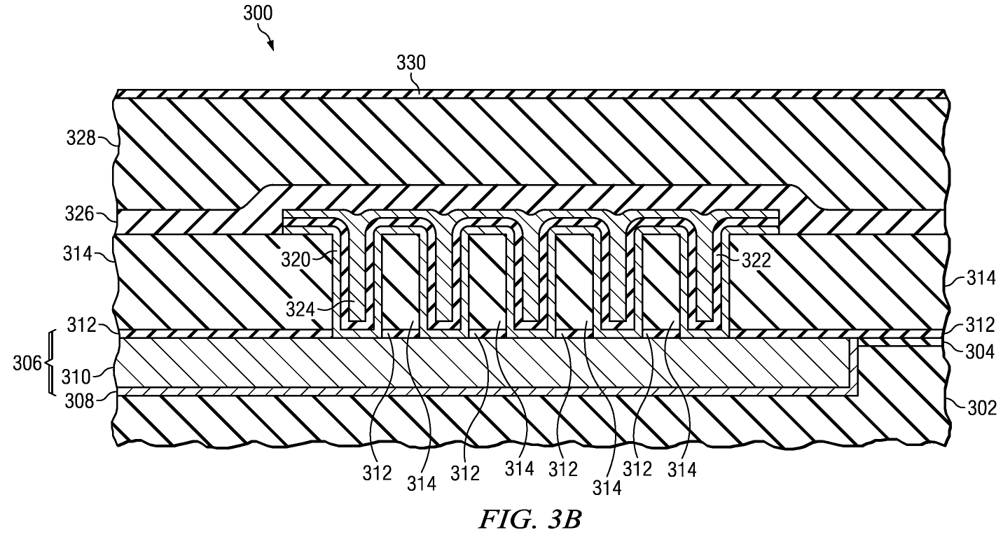

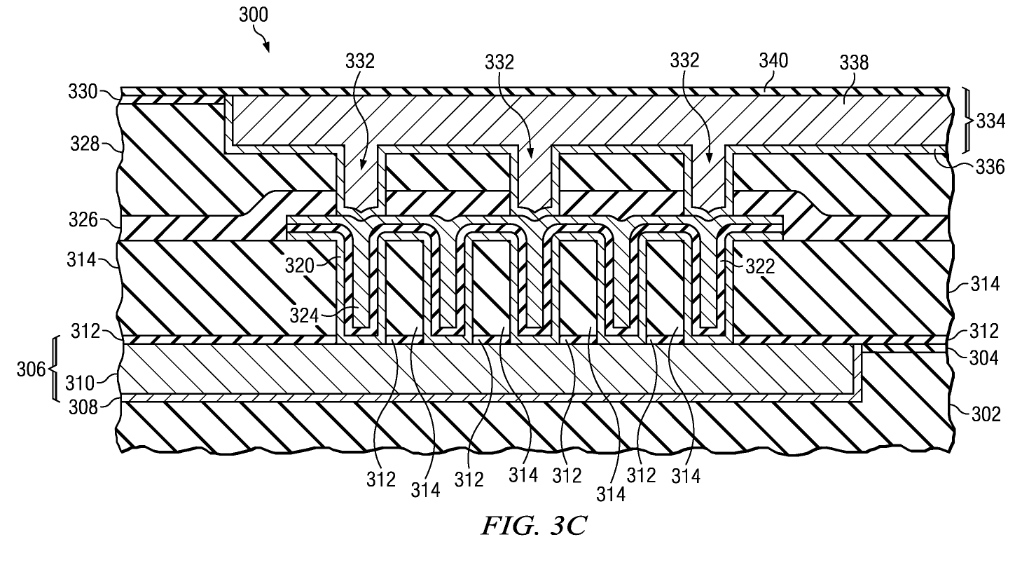

FIGS. 3A-3C illustrate an IC with copper interconnects containing an embedded capacitor formed according to a second embodiment of principles of the invention.

Referring to FIG. 3A, the IC 300 includes a first ILD layer 302, similar to the first ILD layer described in reference to FIG. 2A above. A first cap layer 304 (e.g., 5 to 50 nanometers of silicon nitride, silicon carbide, silicon carbide nitride or a combination of these materials) is formed on a top surface of the first ILD layer 302. A first metal interconnect element 306 is formed in the first ILD layer 302, and includes a first liner metal 308 (e.g., 5 to 20 nanometers thickness of TaN) and a first copper element 310 (e.g., 100 to 1000 nanometers thick). The first metal interconnect element 306 is formed by copper interconnect fabrication processes, such as interconnect trench etching, liner metal deposition, copper seed layer deposition, copper electroplating, and copper chemical mechanical polishing (CMP). Other processes may also be used to form the first metal interconnect element 306. A first etch stop layer 312 (e.g., 5 to 50 nanometers of silicon dioxide, carbon doped silicon dioxide, silicon nitride, silicon carbide, silicon carbide nitride or a combination of these materials) is formed on top surfaces of the first cap layer 304 and the first metal interconnect element 306. A first portion of a second ILD layer 314 (also e.g., silicon dioxide or an electrically insulating material with a dielectric constant lower than silicon dioxide, OSG, SiCO or MSQ) is formed on a top surface of the first etch stop layer 312 and the first metal interconnect element 306, such as by chemical vapor deposition (CVD) or plasma enhanced CVD (PECVD).

Continuing to refer to FIG. 3A, a capacitor trench photoresist pattern 316 is formed on a top surface of the second ILD layer 314, using photolithographic methods such as used to form interconnect via patterns, to define regions for etching capacitor trenches. Capacitor trenches 318 are etched into the second ILD layer 314 and first etch stop layer 312 to expose the first metal interconnect element 306, using etching methods such as used to form interconnect via holes. The capacitor trenches 318 are preferably a minimum width supported by photolithographic and etching processes available for fabrication of the IC 300 and consistent with subsequent formation of capacitor metal and dielectric layers in the capacitor trenches 318.

FIG. 3B depicts the IC 300 after formation of the inventive capacitor by a process sequence similar to the process steps given in reference to FIGS. 2B-2F, above. A capacitor bottom electrode metal layer 320, with properties described above in reference to FIG. 2B, is formed on the top surface of the second ILD layer 314 and surfaces of the second ILD layer 314 and first etch stop layer 312 in the capacitor trenches, making electrical contact with first metal interconnect element 306. A capacitor dielectric layer 322, with the properties described above in reference to FIG. 2C, is formed on a top surface of the bottom electrode layer 320 to form a continuous insulating layer. A capacitor top electrode metal layer 324, with the properties described above in reference to FIG. 2D, is formed on a top surface of the capacitor dielectric layer 322. Lateral boundaries of the illustrated capacitor are defined by a capacitor plate photoresist pattern, and capacitor material outside the lateral boundaries of the capacitor is removed by etching, as described above in reference to FIG. 2E. An optional conformal dielectric sidewall layer 326, with properties as described above in reference to FIG. 2F, is formed on a top surface and lateral surfaces of the top electrode layer 324, and lateral surfaces of the capacitor dielectric layer 322 and bottom electrode layer 320. A second portion of the second ILD layer 328, with properties described above in reference to FIG. 2E, is formed on a top surface of the conformal dielectric sidewall layer 326. A second cap layer 330, (e.g., 5 to 50 nanometers of silicon nitride, silicon carbide, silicon carbide nitride or a combination of these materials) is formed on a top surface of the second portion of the second ILD layer 328.

FIG. 3C depicts the IC 300 after formation a second interconnect element and interconnect vias which make electrical connection to the top electrode layer 324 of the embedded capacitor. Fabrication of copper interconnects and vias is such as performed by either a via-first process sequence or a via-last process sequence. In both process sequences, the following elements are formed. Via holes 332 are etched in the second portion of the second ILD layer 328 and conformal dielectric sidewall layer 326 to expose the top electrode layer 324. An interconnect trench 334 is etched through the second cap layer 330 and into the second ILD layer 328. The interconnect trench 334 and via holes 332 are connected. A second metal liner 336 is formed on the surfaces of the interconnect trench 334 and via holes 332, making electrical contact with the top electrode layer 324. A second copper element 338 is formed on a top surface of the second metal liner 336 in the interconnect trench 334 and via holes 332, by copper interconnect fabrication processes, including liner metal deposition, copper seed layer deposition, copper electroplating, and copper chemical mechanical polishing (CMP). The interconnect trench 334, via holes 332, second metal liner 336 and second copper element 338 may also be formed by other processes. A second etch stop layer 340 (e.g., 5 to 50 nanometers of silicon dioxide, carbon doped silicon dioxide, silicon nitride, silicon carbide, silicon carbide nitride or a combination of these materials) is formed on top surfaces of the second cap layer 304 and the first second copper element 338.

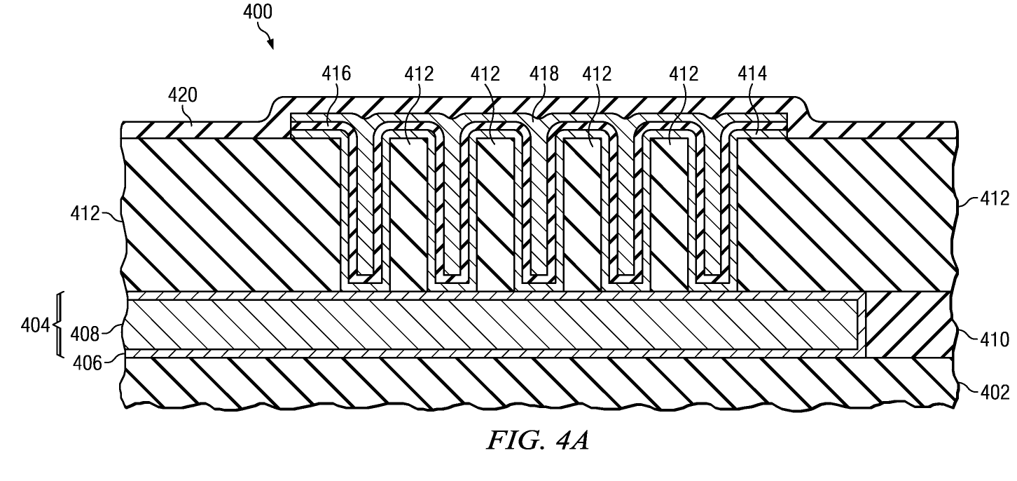

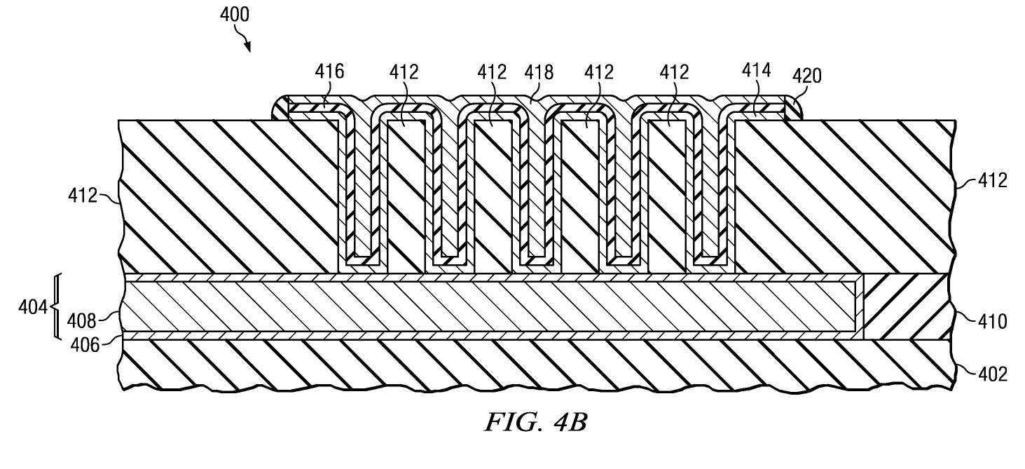

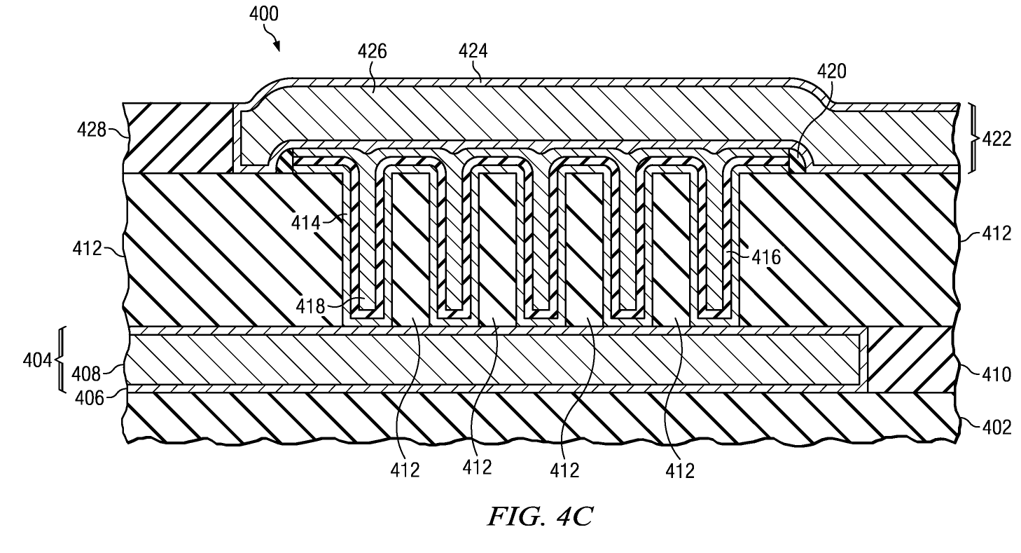

FIGS. 4A-4C illustrate an IC with an embedded capacitor formed according to a third embodiment of the invention.

Referring to FIG. 4A, the IC 400 includes a first ILD layer 402, similar to the first ILD layer described in reference to FIG. 2A above. A first metal interconnect element 404 including a first liner metal 406, with the properties described above in reference to FIG. 2A, and a first aluminum element 408, also with the properties described above in reference to FIG. 2A, is formed on a top surface of the first ILD layer 402. A first IMD layer 410, with the properties described above in reference to FIG. 2A, is formed on the top surface of the first ILD layer 402 adjacent to the first metal interconnect element 404. A second ILD layer 412, with the properties described above in reference to FIG. 2A, is formed on a top surface of the first metal interconnect element 404 and the first IMD layer 410. A capacitor trench photoresist pattern is formed on a top surface of the second ILD layer 412, using photolithographic methods such as used to form interconnect via patterns, to define regions for etching capacitor trenches. Capacitor trenches are etched into the second ILD layer 412 to expose the first metal interconnect element 404, using etching methods such as used to form interconnect via holes. The capacitor trenches are preferably a minimum width supported by photolithographic and etching processes available for fabrication of the IC 400 and consistent with subsequent formation of capacitor metal and dielectric layers in the capacitor trenches.

Still referring to FIG. 4A, the inventive capacitor is formed by a process sequence similar to the process steps recited in reference to FIGS. 2B-2F. A capacitor bottom electrode metal layer 414, with the properties as described above in reference to FIG. 2B, is formed on the top surface of the second ILD layer 412 and surfaces of the second ILD layer 412 in the capacitor trenches, making electrical contact with first metal interconnect element 404. Ad capacitor dielectric layer 416, with properties as described above in reference to FIG. 2C, is formed on a top surface of the bottom electrode layer 414 to form a continuous insulating layer. A capacitor top electrode metal layer 418, with the properties described above in reference to FIG. 2D, is formed on a top surface of the capacitor dielectric layer 416. Lateral boundaries of the inventive capacitor are defined by a capacitor plate photoresist pattern, and capacitor material outside the lateral boundaries of the capacitor is removed by etching, as described above in reference to FIG. 2E. A conformal dielectric sidewall layer 420, with the properties described above in reference to FIG. 2F, is formed on a top surface and lateral surfaces of the top electrode layer 418, and lateral surfaces of the capacitor dielectric layer 416 and bottom electrode layer 414.

FIG. 4B depicts the IC 400 after an anisotropic sidewall etchback process in which material in the conformal dielectric sidewall layer 420 is removed from top surfaces of the top electrode layer 418 and second ILD layer 412, leaving material on the lateral surfaces of the top electrode layer 418, capacitor dielectric layer 416 and bottom electrode layer 414. The purpose of the anisotropic sidewall etchback process is to expose the top surface of the top electrode layer 418 for electrical contact while protecting the lateral surfaces of the top electrode layer 418 and bottom electrode layer 414 from short circuiting by deposited metal in subsequent fabrication process operations. In an alternate embodiment, material in the conformal dielectric sidewall layer 420 may be removed from the top surface of the top electrode layer 418 by a CMP process. Other processes compatible with fabrication of the IC 400 may be used to expose the top surface of the top electrode layer 418 for electrical contact while protecting the lateral surfaces of the top electrode layer 418 and bottom electrode layer 414.

FIG. 4C depicts the IC 400 after formation of a second metal interconnect element 422 on top surfaces of the second ILD layer 412 and top electrode layer 418 so as to make electrical contact to the top electrode layer 418. The second metal interconnect element 422 is, e.g., formed by a similar set of processes as used to form the first metal interconnect element 404, and includes a second liner metal 424, with the properties described above in reference to FIG. 2G, and a second aluminum element 426, also with the properties described above in reference to FIG. 2G. The second metal interconnect element 422 is, e.g., as thick as, or thicker than, the first metal interconnect element 404. A second IMD layer 428 is formed on the top surface of the second ILD layer 412 adjacent to the second metal interconnect element 422, e.g., of the same material and formed by the same process as the first IMD layer 410.

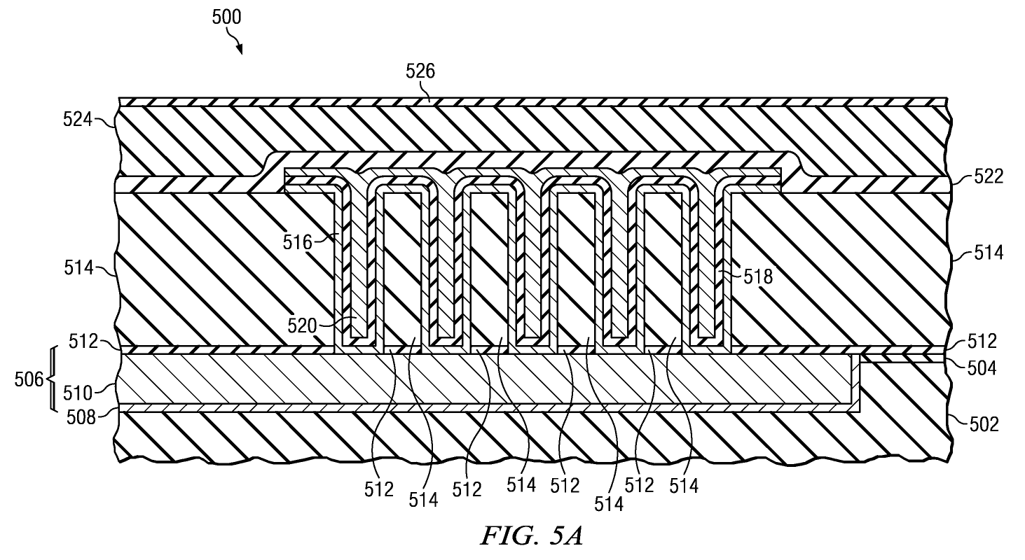

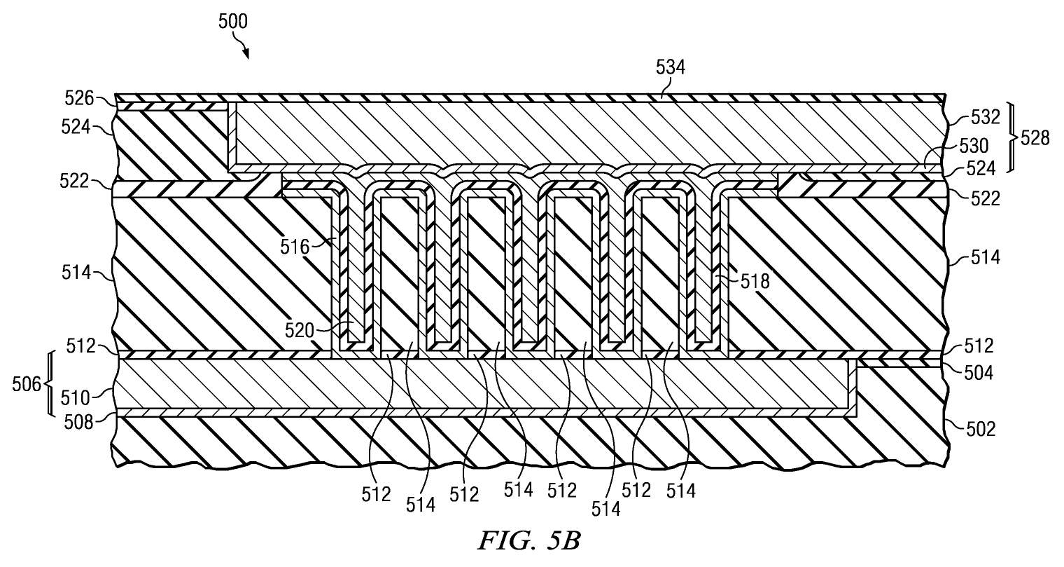

FIGS. 5A-5B illustrate an IC with copper interconnects containing an embedded capacitor formed according to a fourth embodiment of principles of the invention.

Referring to FIG. 5A, the IC 500 includes a first ILD layer 502, similar to the first ILD layer described in reference to FIG. 2A above. A first cap layer 504, with the properties described above in reference to FIG. 3A, is formed on a top surface of the first ILD layer 502. A first metal interconnect element 506 is formed in the first ILD layer 502, and includes a first liner metal 508, with the properties described above in reference to FIG. 3A, and a first copper element 510, also with the properties described above in reference to FIG. 3A. The first metal interconnect element 506 may also be formed by other processes. A first etch stop layer 512, with the properties described above in reference to FIG. 3A, is formed on top surfaces of the first cap layer 504 and the first metal interconnect element 506. A first portion of a second ILD layer 514, with the properties described above in reference to FIG. 3A, is formed on a top surface of the first etch stop layer 512 and the first metal interconnect element 506.

Still referring to FIG. 5A, a capacitor trench photoresist pattern is formed on a top surface of the first portion of the second ILD layer 514, using photolithographic methods such as used to form interconnect via patterns, to define regions for etching capacitor trenches. Capacitor trenches are etched into the first portion of the second ILD layer 514 and first etch stop layer 512 to expose the first metal interconnect element 506, using etching methods such as used to form interconnect via holes. The capacitor trenches are preferably a minimum width supported by photolithographic and etching processes available for fabrication of the IC 500 and consistent with subsequent formation of capacitor metal and dielectric layers in the capacitor trenches. An embedded capacitor is formed in the IC 500 by a process sequence similar to the process steps recited in reference to FIGS. 2B-2F. A capacitor bottom electrode metal layer 516, with the properties described above in reference to FIG. 2B, is formed on the top surface of the first portion of the second ILD layer 514 and surfaces of the first portion of the second ILD layer 514 and first etch stop layer 512 in the capacitor trenches, making electrical contact with first metal interconnect element 506. A capacitor dielectric layer 518, with the properties described above in reference to FIG. 2C, is formed on a top surface of the bottom electrode layer 516 to form a continuous insulating layer. A capacitor top electrode metal layer 520, with the properties described above in reference to FIG. 2D, is formed on a top surface of the capacitor dielectric layer 518. Lateral boundaries of the inventive capacitor are defined by a capacitor plate photoresist pattern, and capacitor material outside the lateral boundaries of the capacitor is removed by etching, as described above in reference to FIG. 2E. An optional conformal dielectric sidewall layer 522 with the properties described above in reference to FIG. 2F is formed on a top surface and lateral surfaces of the top electrode layer 520, and lateral surfaces of the capacitor dielectric layer 518 and bottom electrode layer 516. A second portion of the second ILD layer 524 with the properties described above in reference to FIG. 2E is formed on a top surface of the conformal dielectric sidewall layer 522. A second cap layer 526 (e.g., 5 to 50 nanometers of silicon nitride, silicon carbide, silicon carbide nitride or a combination of these materials) is formed on a top surface of the second portion of the second ILD layer 524.

FIG. 5B depicts the IC 500 after formation a second interconnect element 528 which makes electrical connection to the top electrode layer 520 of the on-chip 3-D embedded capacitor, as described above in reference to FIG. 3C. An interconnect trench is etched through the second cap layer 526 and into the second ILD layer 524. A second metal liner 530 is formed on the surfaces of the interconnect trench, making electrical contact with the top electrode layer 520. A second copper element 532 is formed on a top surface of the second metal liner 530 in the interconnect trench, by copper interconnect fabrication processes, including liner metal deposition, copper seed layer deposition, copper electroplating, and copper CMP. The second interconnect element 528 may be formed by other processes. A second etch stop layer 534 (e.g., 5 to 50 nanometers of silicon dioxide, carbon doped silicon dioxide, silicon nitride, silicon carbide, silicon carbide nitride or a combination of these materials) is formed on top surfaces of the second cap layer 526 and the second interconnect element 528.

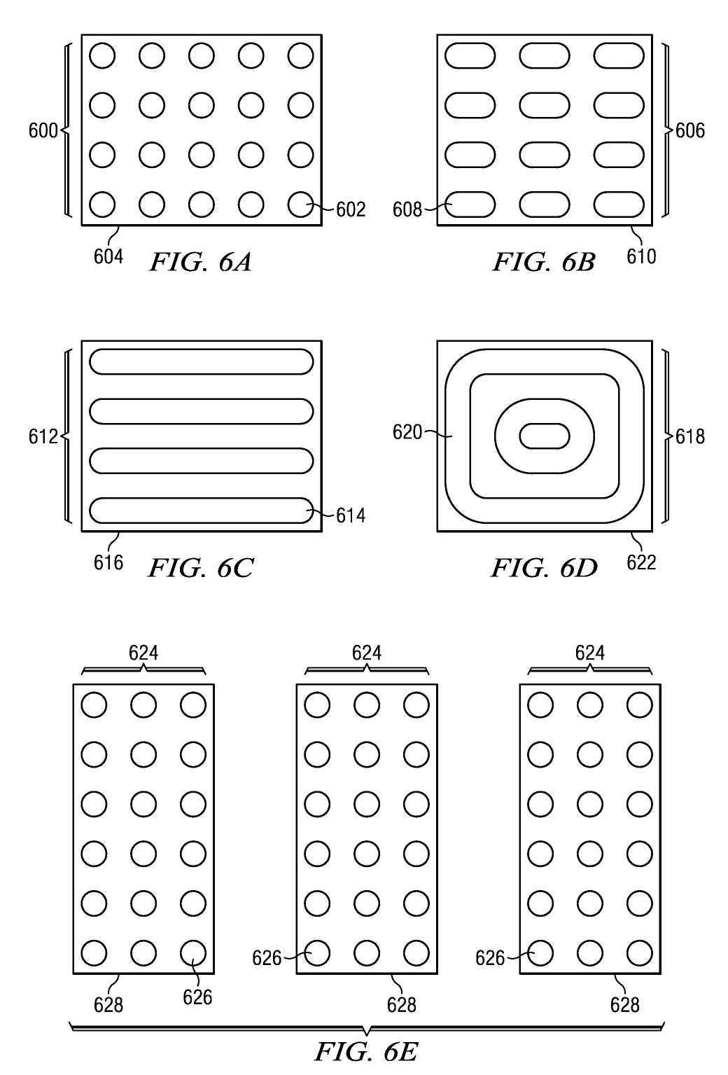

FIGS. 6A-6E illustrate examples of capacitor trench patterns usable in various embodiments of principles of the invention.

FIG. 6A depicts a rectangular array 600 of capacitor trenches 602 extending to a lateral boundary 604 of an embedded capacitor, in which each trench has a lateral trench length substantially equal to a lateral trench width. The capacitor trenches depicted in FIG. 6A may also be referred to as capacitor vias, due to the 1:1 length-to-width ratio. An advantage of such embodiment is that capacitance density may be maximized for common IC fabrication process sequences.

FIG. 6B depicts a rectangular array 606 of short capacitor trenches 608 extending to a lateral boundary 610 of an embedded capacitor, in which each trench has a lateral trench length longer than a lateral trench width but less than a lateral length of the lateral boundary 610. An advantage of such embodiment is that capacitance density may be maximized for IC fabrication process sequences which place a relatively higher limit on a minimum separation of capacitor trenches.

FIG. 6C depicts a linear array 612 of long capacitor trenches 614 extending to a lateral boundary 616 of an embedded capacitor, in which each trench has a lateral trench length that extends to a lateral length of the lateral boundary 610. An advantage of such embodiment is that capacitance density may be maximized for IC fabrication process sequences which are able to fabricate long capacitor trenches at a higher density than capacitor vias.

FIG. 6D depicts a concentric array 618 of closed loop capacitor trenches 620 extending to a lateral boundary 622 of an embedded capacitor.

FIG. 6E depicts an embedded capacitor which includes a set of rectangular arrays 624 of capacitor vias or trenches 626 in separate lateral boundaries 628. The arrays 624 may be positioned in an IC and connected by interconnect elements to form an embedded capacito. An advantage of such embodiment is that the arrays 624 may be positioned in an IC to optimize a layout efficiency and/or performance of the IC.

An advantage of the embodiments described above is that they may be implemented in any region of an interlevel dielectric layer in an IC which is clear of interconnect elements, thereby providing flexibility in the design and layout of the IC. A further advantage is that the embedded capacitor may be distributed among more than one such clear region in an IC, providing more flexibility in the design and layout of the IC. Yet another advantage is that the embedded capacitor may be distributed among clear regions in more than one interlevel dielectric layer, providing additional flexibility in the design and layout of the IC.

Those skilled in the art to which the invention relates will appreciate that many other embodiments and modifications are possible within the scope of the claimed invention.

What is claimed is:

1. A method of forming an IC including a capacitor, comprising:
forming a first interconnect element;
forming an interlevel dielectric layer over the first interconnect element;
forming vertical capacitor trenches in the interlevel dielectric layer which expose the first interconnect element;
forming a capacitor bottom electrode metal layer in the capacitor trenches and over the interlevel dielectric layer in a region defined for the capacitor; whereby the bottom electrode metal layer is electrically connected to said first interconnect element;
forming a capacitor dielectric layer over the bottom electrode metal layer;
forming a capacitor top electrode metal layer over the capacitor dielectric layer; and
forming a second interconnect element over the top electrode metal layer whereby the second interconnect element is electrically connected to said top electrode metal layer.

2. The method of claim 1, wherein each capacitor trench has a lateral trench length substantially equal to a lateral trench width, and the capacitor trenches are arranged in a regular array.

3. The method of claim 1, wherein the interlevel dielectric layer is at least 1 micron thick; and a capacitance density of the capacitor is greater than 20 nanofarads/mm².

4. The method of claim 1, wherein the interlevel dielectric layer is at least 2 microns thick; and a capacitance density of the capacitor is greater than 40 nanofarads/mm².

5. The method of claim 1, wherein the first and second interconnect elements are comprised of aluminum.

6. The method of claim 1, wherein the first and second interconnect elements are comprised of c copper.

7. The method of claim 1, further comprising forming a second interlevel dielectric layer over the top electrode metal layer and below the second interconnect element; and forming a conductive interconnect via in the second interlevel dielectric layer which makes electrical contact to the top electrode metal layer and the second interconnect element.

8. An integrated circuit including an on-chip capacitor, comprising:
an interlevel dielectric layer;
vertical capacitor trenches formed in the interlevel dielectric layer;
a capacitor bottom electrode metal layer formed in the capacitor trenches and over the interlevel dielectric layer in a region defined for the capacitor;
a capacitor dielectric layer formed over the bottom electrode metal layer; and
a capacitor top electrode metal layer formed over capacitor dielectric layer.

9. The integrated circuit of claim 8, wherein each capacitor trench has a lateral trench length substantially equal to a lateral trench width, and the capacitor trenches are arranged in a regular array.

10. The integrated circuit of claim 8, wherein the interlevel dielectric layer is at least 1 micron thick; and a capacitance density of the capacitor is greater than 20 nanofarads/mm².

11. The integrated circuit of claim 1, wherein the interlevel dielectric layer is at least 2 microns thick; and a capacitance density of the capacitor is greater than 40 nanofarads/mm².

12. The integrated circuit of claim 1, wherein the bottom electrode metal layer comprises titanium nitride (TiN); and the top electrode metal layer comprises TiN.

13. The integrated circuit of claim 1, wherein the capacitor dielectric layer is between 5 and 15 nanometers thick.

14. An integrated circuit including an on-chip capacitor, comprising:
a first interconnect element;
an interlevel dielectric layer formed over the first interconnect element;
vertical capacitor trenches formed in the interlevel dielectric layer down to the first interconnect element;
a capacitor bottom electrode metal layer formed in the capacitor trenches and over the interlevel dielectric layer in a region defined for the capacitor, with the bottom electrode metal layer in electrical contact to the first interconnect element;
a capacitor dielectric layer formed over the bottom electrode metal layer;
a top electrode metal layer formed over the capacitor dielectric layer; and
a second interconnect element formed above, and in electrical contact with, the top electrode metal layer.

15. The integrated circuit of claim 14, wherein the capacitor trenches have lateral trench lengths substantially equal to lateral trench widths, and the capacitor trenches are arranged in a regular array.

16. The integrated circuit of claim 14, wherein the interlevel dielectric layer is at least 1 micron thick; and a capacitance density of the capacitor is greater than 20 nanofarads/mm².

17. The integrated circuit of claim 14, wherein the interlevel dielectric layer is at least 2 microns thick; and a capacitance density of the capacitor is greater than 40 nanofarads/mm².

18. The integrated circuit of claim 14, wherein the first and second interconnect elements are comprised of aluminum.

19. The integrated circuit of claim 14, wherein the first and second interconnect elements are comprised of copper.

20. The integrated circuit of claim 14, further comprising a second interlevel dielectric layer formed over the top electrode metal layer and below the second interconnect element; and a conductive interconnect via formed in the second interlevel dielectric layer in electrical contact with the top electrode metal layer and with the second interconnect element.
